(19) United States
(12) Patent Application Publication
(10) Pub. No.: US 2024/0213705 A1
(43) Pub. Date: Jun. 27, 2024

(54) ELECTRICAL RECEPTACLE CONNECTOR

(71) Applicant: ALL BEST PRECISION TECHNOLOGY CO., LTD., Taoyuan City (TW)

(72) Inventor: Haven Yang, TAOYUAN CITY (TW)

(73) Assignee: ALL BEST PRECISION TECHNOLOGY CO., LTD., Taoyuan City (TW)

(21) Appl. No.: 18/209,481

(22) Filed: Jun. 14, 2023

(30) Foreign Application Priority Data
Dec. 27, 2022 (TW) 111150161

(51) Int. Cl. H01R 13/506

(52) U.S. Cl. CPC H01R 13/506

(57) ABSTRACT

An electrical receptacle connector includes a case device and a heat dissipating device. The case device includes two case portions for cooperatively defining a receiving space between two accommodating spaces of the two case portions and two lateral windows at two sides of the receiving space. The heat dissipating device includes a first heat dissipating component. The first heat dissipating component is a one-piece structure and includes a first heat dissipating portion, a second heat dissipating portion and a third heat dissipating portion. The first heat dissipating portion is at least partially disposed inside the receiving space and passes through the two lateral windows. The second heat dissipating portion and the third heat dissipating portion are integrally connected to two ends of the first heat dissipating portion respectively. The two case portions are at least partially located between the second heat dissipating portion and the third heat dissipating portion.

### BACKGROUND OF THE INVENTION

### 1. Field of the Invention

The present invention relates to an electrical receptacle connector, and more specifically, to an electrical receptacle connector with a heat dissipating function and easy assembly.

### 2. Description of the Prior Art

Electrical connectors are widely used in different applications e.g., for power and/or signal transmission between host devices and external devices. The electrical connector generates more heat with increase of a transmission speed of the electrical connector. In order to avoid any negative impact due to a high temperature, the electrical connector is usually provided with a heat dissipating component for dissipating the heat. However, such electrical connector cannot be assembled easily. Therefore, an improvement is needed.

### SUMMARY OF THE INVENTION

Therefore, it is an objective of the present invention to provide an electrical receptacle connector with a heat dissipating function and easy assembly for solving the aforementioned problem.

In order to achieve the aforementioned objective, the present invention discloses an electrical 1 receptacle connector. The electrical receptacle connector includes a case device, a terminal device and a heat dissipating device. The case device includes a first case portion and a second case portion. A first slot structure and a first accommodating space are formed on the first case portion. A second slot structure and a second accommodating space are formed on the second case portion. The first case portion and the second case portion are arranged along a first direction. The first case portion and the second case portion cooperatively define a first receiving space located between the first accommodating space and the second accommodating space and two first lateral windows located at two opposite sides of the first receiving space. The terminal device includes a first contact set and a second contact set. The first contact set is at least partially disposed inside the first accommodating space. The second contact set is at least partially disposed inside the second accommodating space. The heat dissipating device includes a first heat dissipating component. The first heat dissipating component is a one-piece structure and includes a first heat dissipating portion, a second heat dissipating portion and a third heat dissipating portion. The first heat dissipating portion is at least partially disposed inside the first receiving space and passes through the two first lateral windows. A first abutting structure is formed on the first heat dissipating portion. The second heat dissipating portion is integrally connected to a first end of the first heat dissipating portion. The third heat dissipating portion is integrally connected to a second end of the first heat dissipating portion opposite to the first end of the first heat dissipating portion. The first case portion and the second case portion are at least partially located between the second heat dissipating portion and the third heat dissipating portion.

According to an embodiment of the present invention, a thickness of the first heat dissipating portion along the first direction is greater than a thickness of the second heat dissipating portion along a second direction and greater than a thickness of the third heat dissipating portion along the second direction, and the first direction is perpendicular to the second direction.

According to an embodiment of the present invention, a length of the first heat dissipating portion along a second direction is greater than a thickness of the case device along the second direction, and the first direction is perpendicular to the second direction.

According to an embodiment of the present invention, at least one wall of the second case portion is integrally connected to at least one wall of the first case portion. The case device further includes a supporting component abutting against the first case portion and the second case portion and at least partially located inside the first receiving space, and the first heat dissipating component is assembled with the case device by at least inserting the first heat dissipating portion into the first receiving space along an inserting direction different from the first direction.

According to an embodiment of the present invention, at least one first engaging structure is formed on the first case portion. At least one second engaging structure is formed on the second case portion. The second case portion is detachably assembled with the first case portion by an engagement of the at least one second engaging structure and the at least one first engaging structure. At least one supporting structure is formed on one of the first case portion and the second case portion. The at least one supporting structure abuts against another one of the first case portion and the second case portion when the second case portion is detachably assembled with the first case portion, and the first heat dissipating component is assembled with the case device by stacking the first case portion, the first heat dissipating portion and the second case portion along the first direction sequentially.

According to an embodiment of the present invention, a first heat dissipating structure is formed on the first heat dissipating portion and for increasing a heat dissipating area of the first heat dissipating portion, and a heat dissipating abutting structure is formed on the second case portion and abuts against the first heat dissipating structure.

According to an embodiment of the present invention, the electrical receptacle connector further includes a clipping component and a second heat dissipating component disposed on a side of the second case portion away from the first heat dissipating portion. An abutting structure and a heat dissipating structure are formed on the second heat dissipating component. The abutting structure at least partially passes through the second slot structure. The heat dissipating structure is for increasing a heat dissipating area of the second heat dissipating component, and the second heat dissipating component is clamped by and located between the clipping component and the case device.

According to an embodiment of the present invention, the electrical receptacle connector further includes at least one light guiding component fixed on the second case portion. The heat dissipating structure is a plate-fin structure, and the at least one light guiding component is partially located between two corresponding fins of the plate-fin structure.

According to an embodiment of the present invention, the electrical receptacle connector further includes a finger device assembled with the case device and for preventing an electromagnetic interference.

According to an embodiment of the present invention, a height of the first accommodating space along the first direction is equal to a height of the second accommodating space along the first direction and greater than a height of the first receiving space along the first direction.

According to an embodiment of the present invention, the case device further includes a third case portion and a fourth case portion. A third slot structure and a third accommodating space are formed on the third case portion. A fourth slot structure and a fourth accommodating space are formed on the fourth case portion. The third case portion and the fourth case portion are arranged along the first direction. The third case portion and the fourth case portion cooperatively define a second receiving space located between the third accommodating space and the fourth accommodating space and a second lateral window located at a side of the second receiving space. The third case portion and the first case portion are arranged along a second direction. The fourth case portion and the second case portion are arranged along the second direction. The terminal device further includes a third contact set and a fourth contact set. The third contact set is at least partially disposed inside the third accommodating space. The fourth contact set is at least partially disposed inside the fourth accommodating space. The first heat dissipating portion is disposed inside the first receiving space and the second receiving space and passes through the two first lateral windows and the second lateral window. The first abutting structure and a first auxiliary abutting structure are formed on the first heat dissipating portion and respectively pass through the first slot structure and the third slot structure. The second case portion and the fourth case portion abut against the first heat dissipating portion. The first case portion, the second case portion, the third case portion and the fourth case portion are at least partially located between the second heat dissipating portion and the third heat dissipating portion, and the first direction is perpendicular to the second direction.

In summary, in the present invention, the first heat dissipating component is the one-piece structure, and due to a low heat resistance between the first heat dissipating portion and the second heat dissipating portion and a low heat resistance between the first heat dissipating portion and the third heat dissipating portion, heat conducted to the first heat dissipating portion can be conducted to the second heat dissipating portion and the third heat dissipating portion rapidly. Besides, when it is desired to assemble the electrical receptacle connector, it only has to stack the first case portion, the first heat dissipating portion and the second case portion along the first direction sequentially, or insert the first heat dissipating portion into the first receiving space between the first case portion and the second case portion along the inserting direction, for achieving assembly of the first heat dissipating component and the case device. Therefore, the electrical receptacle connector has an advantage of easy assembly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams of an electrical receptacle connector at different views according to a first embodiment of the present invention.

FIG. 3 and FIG. 4 are exploded diagrams of the electrical receptacle connector at different views according to the first embodiment of the present invention.

FIG. 5 is a sectional diagram of the electrical receptacle connector according to the first embodiment of the present invention.

FIG. 6 is a partial diagram of the electrical receptacle connector according to the first embodiment of the present invention.

FIG. 7 is a schematic diagram of an electrical receptacle connector according to a second embodiment of the present invention.

FIG. 8 is a partial exploded diagram of the electrical receptacle connector according to the second embodiment of the present invention.

FIG. 9 is a partial diagram of the electrical receptacle connector according to the second embodiment of the present invention.

FIG. 10 is a schematic diagram of an electrical receptacle connector according to a third embodiment of the present invention.

FIG. 11 is a partial exploded diagram of the electrical receptacle connector according to the third embodiment of the present invention.

FIG. 12 is a partial diagram of the electrical receptacle connector according to the third embodiment of the present invention.

FIG. 13 is a sectional diagram of the electrical receptacle connector according to the third embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “left”, “right”, “front”, “rear”, etc., is used with reference to the orientation of the Figure (s) being described. The components of the present invention can be positioned in a number of different orientations. As such, the directional terminology is used for purposes of illustration and is in no way limiting. Accordingly, the drawings and descriptions will be regarded as illustrative in nature and not as restrictive. Also, if not specified, the term “connect” is intended to mean either an indirect or direct mechanical connection. Thus, if a first device is connected to a second device, that connection may be through a direct mechanical connection, or through an indirect mechanical connection via other devices and connections.

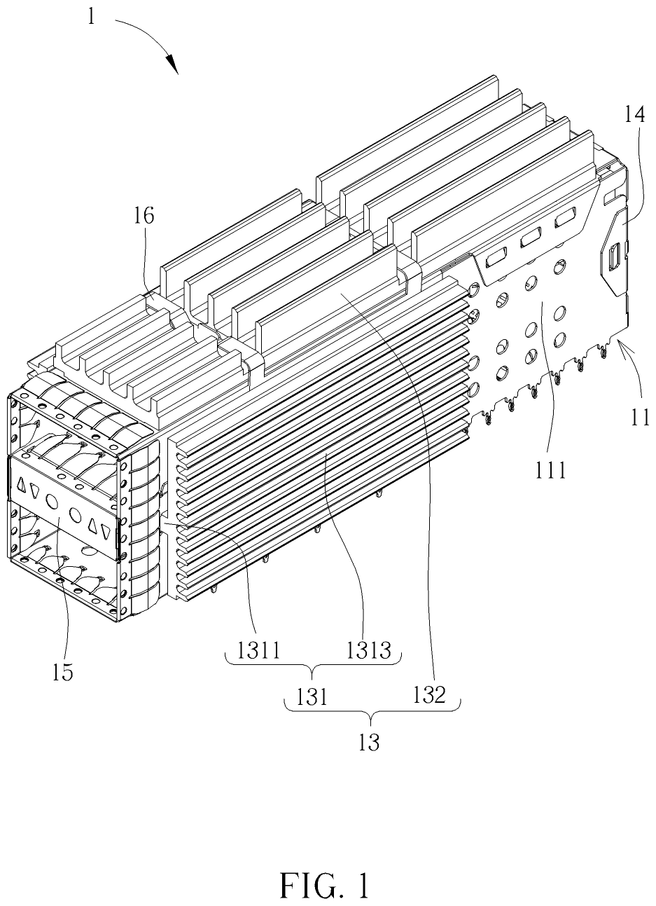

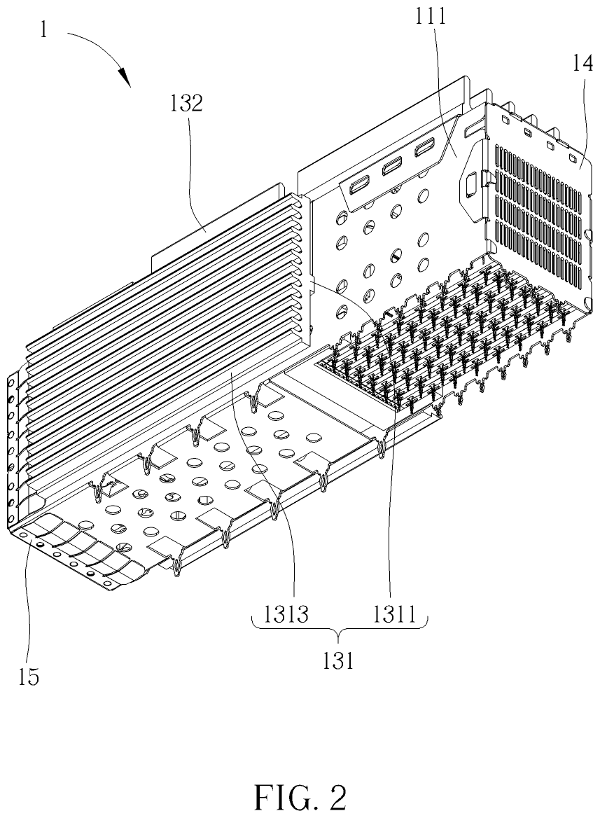

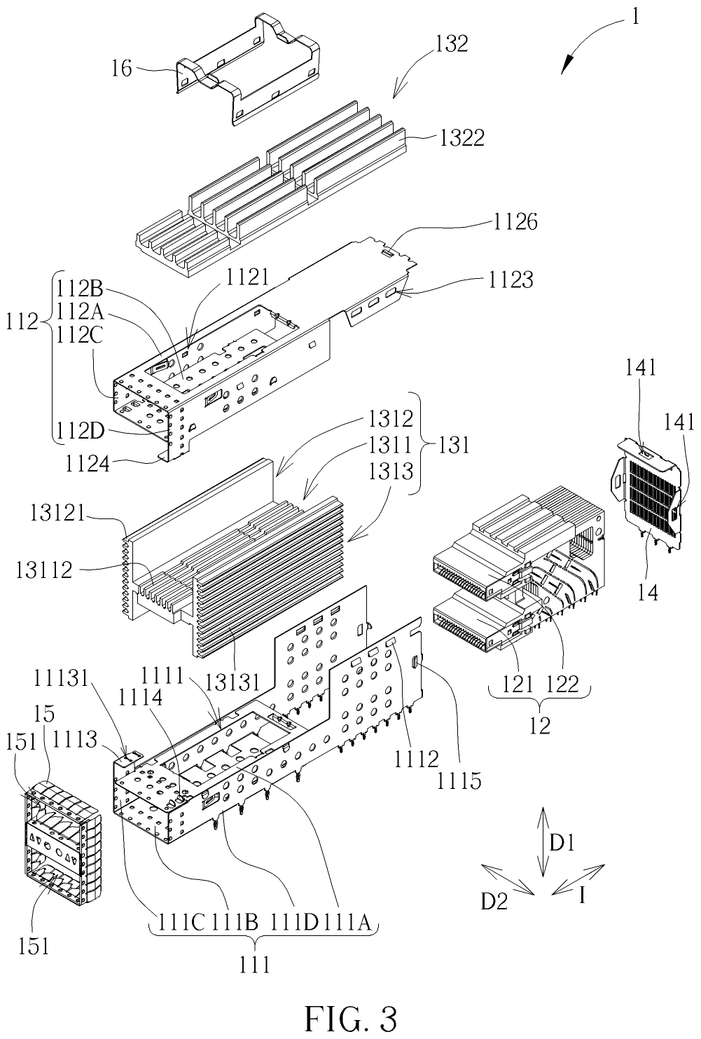

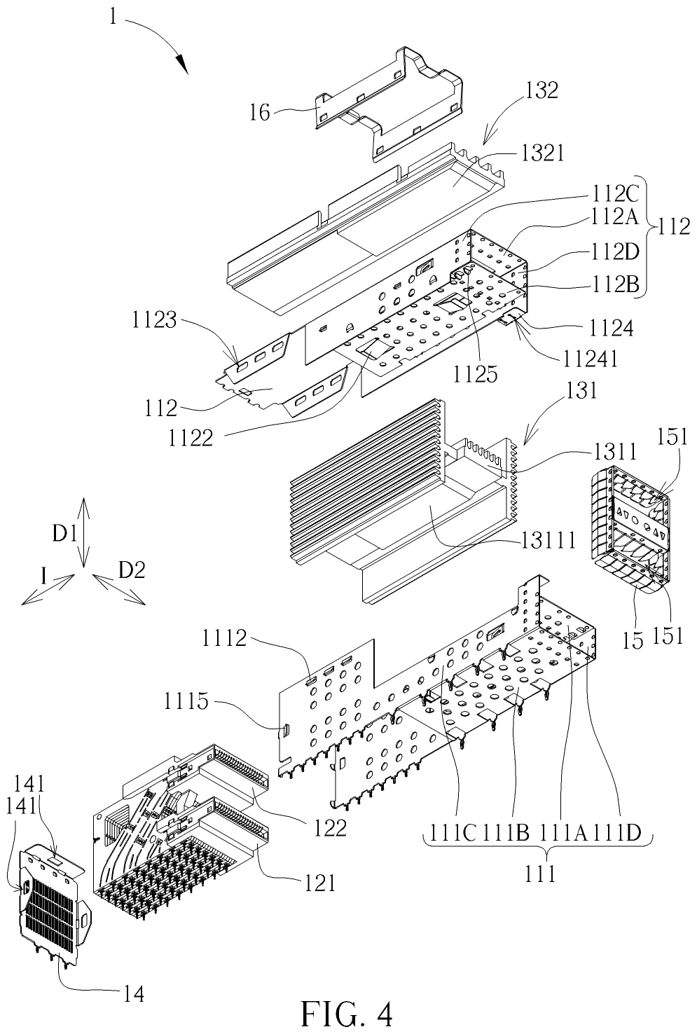

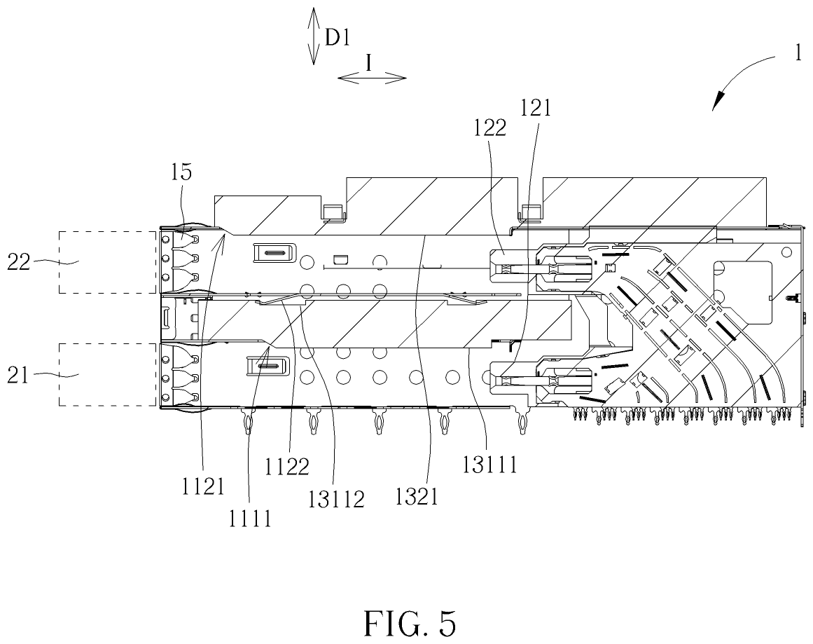

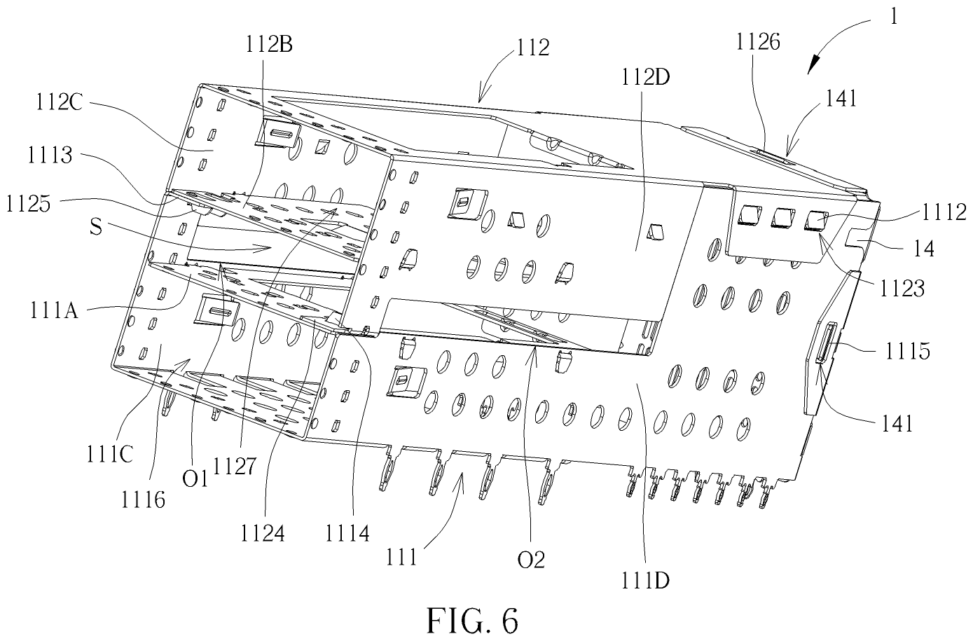

Please refer to FIG. 1 to FIG. 6. FIG. 1 and FIG. 2 are schematic diagrams of an electrical receptacle connector 1 at different views according to a first embodiment of the present invention. FIG. 3 and FIG. 4 are exploded diagrams of the electrical receptacle connector 1 at different views according to the first embodiment of the present invention. FIG. 5 is a sectional diagram of the electrical receptacle connector 1 according to the first embodiment of the present invention. FIG. 6 is a partial diagram of the electrical receptacle connector 1 according to the first embodiment of the present invention. As shown in FIG. 1 to FIG. 6, the electrical receptacle connector 1 includes a case device 11, a terminal device 12 and a heat dissipating device 13. The case device 11 includes a first case portion 111 and a second case portion 112. The first case portion 111 and the second case portion 112 are arranged along a first direction D1. A first accommodating space 1116 is formed on the first case portion 111. A second accommodating space 1127 is formed on the second case portion 112. The first case portion 111 and the second case portion 112 cooperatively define a first receiving space S located between the first accommodating space 1116, and the first case portion 111 and the second case portion 112 further cooperatively define the second accommodating space 1127 and two first lateral windows O1, O2 located at two opposite sides of the first receiving space S. The terminal device 12 includes a first contact set 121 and a second contact set 122. The first contact set 121 is at least partially accommodated inside the first accommodating space 1116. The second contact set 122 is at least partially accommodated inside the second accommodating space 1127.

The heat dissipating device 13 includes a first heat dissipating component 131 and a second heat dissipating component 132. The first heat dissipating component 131 includes a first heat dissipating portion 1311, a second heat dissipating portion 1312 and a third heat dissipating portion 1313. The first heat dissipating portion 1311 is at least partially disposed between the first case portion 111 and the second case portion 112. Specifically, the first heat dissipating portion 1311 is at least partially disposed inside the first receiving space S between the first case portion 111 and the second case portion 112 and passes through the two first lateral windows O1, O2, i.e., a first end of the first heat dissipating portion 1311 and a second end of the first heat dissipating portion 1311 opposite to the first end of the first heat dissipating portion 1311 respectively protrude out of the two first lateral windows O1, O2. The second heat dissipating portion 1312 is integrally connected to the first end of the first heat dissipating portion 1311. The third heat dissipating portion 1313 is integrally connected to the second end of the first heat dissipating portion 1311. The first case portion 111 and the second case portion 112 are at least partially located between the second heat dissipating portion 1312 and the third heat dissipating portion 1313. The second heat dissipating component 132 is disposed on a side of the second case portion 112 away from the first heat dissipating portion 1311.

In this embodiment, the first heat dissipating component 131 can be formed in an H shape. A height of the first accommodating space 1116 along the first direction D1 can be equal to a height of the second accommodating space 1127 along the first direction and greater than a height of the first receiving space S along the first direction D1. However, the present invention is not limited to this embodiment. The shape of the first heat dissipating component and the heights of the first accommodating space, the second accommodating space and the first receiving space along the first direction can be determined according to practical demands.

Furthermore, in this embodiment, the electrical receptacle connector 1 can be an optical communication connector, and the first contact set 121 and the second contact set 122 can be two optical communication contact sets. However, the present invention is not limited to this embodiment. For example, in another embodiment, the electrical receptacle connector can be an electrical communication connector, and the first contact set and the second contact set can be two electrical communication contact sets.

In addition, the electrical receptacle connector 1 further includes a covering body 14, a finger device 15 and a clipping component 16. The covering body 14 is connected to the case device 11 and at least partially covers the terminal device 12. Two opening portions 151 are formed on the finger device 15 and respectively located at positions corresponding to the first case portion 111 and the second case portion 112. The finger device 15 is assembled with the case device 11 along an inserting direction I and for preventing an electromagnetic interference. The clipping component 16 is for engaging with the second case portion 112, and the second heat dissipating component 132 is clamped by and located between the clipping component 16 and the case device 11.

The first contact set 121 and the second contact set 122 can be two receptacle contact sets in accordance with Universal Serial Bus (USB) specification. A first electrical plug connector 21 and a second electrical plug connector 22 can be two electrical plug connectors in accordance with Universal Serial Bus (USB) specification. However, the present invention is not limited thereto.

As shown in FIG. 3 to FIG. 6, a first slot structure 1111 is formed on the first case portion 111. A first abutting structure 13111 is formed on the first heat dissipating portion 1311 and at least partially passes through the first slot structure 1111. A second slot structure 1121 is formed on the second case portion 112. A second abutting structure 1321 is formed on the second heat dissipating component 132 and at least partially passes through the second slot structure 1121. The first abutting structure 13111 can abut against the first electrical plug connector 21 for conducting heat generated by the first electrical plug connector 21 to the first heat dissipating portion 1311 by the first abutting structure 13111. The second abutting structure 1321 can abut against the second electrical plug connector 22 for conducting heat generated by the second electrical plug connector 22 to the second heat dissipating component 132 by the second abutting structure 1321.

In this embodiment, the first abutting structure 13111 and the second abutting structure 1321 can be two protruding platform structures. However, the present invention is not limited to this embodiment. For example, in another embodiment, the first abutting structure 13111 or the second abutting structure 1321 can be a plate-shaped structure or a column-shaped structure.

As shown in FIG. 3 to FIG. 5, in order to allow the first heat dissipating portion 1311 and the second heat dissipating component 132 to dissipate the heat conducted from the first electrical plug connector 21 and the second electrical plug connector 22 to the air rapidly, a first heat dissipating structure 13112 is further formed on the first heat dissipating portion 1311 and for increasing a heat dissipating area of the first heat dissipating portion 1311, and a heat dissipating structure 1322 is further formed on the second heat dissipating component 132 and for increasing a heat dissipating area of the second heat dissipating component 132.

In this embodiment, the first heat dissipating structure 13112 and the heat dissipating structure 1322 can be two thermal fin structures, such as two plate-fin structures. However, the present invention is not limited to this embodiment. For example, in another embodiment, the first heat dissipating structure or the heat dissipating structure can be a column-fin structure.

As shown in FIG. 4 to FIG. 5, the first case portion 111 and the second case portion 112 not only abut against the first electrical plug connector 21 and the second electrical plug connector 22 respectively but also abut against each other. Therefore, the heat generated by the first electrical plug connector 21 and the second electrical plug connector 22 can be conducted to the second case portion 112 directly and/or indirectly. In order to avoid heat accumulation, at least one heat dissipating abutting structure 1122 is formed on the second case portion 112 and abuts against the first heat dissipating structure 13112, so that the heat conducted to the second case portion 112 can be conducted to the first heat dissipating structure 13112 by the heat dissipating abutting structure 1122.

In this embodiment, the heat dissipating abutting structure 1122 can be a resilient arm structure. However, the present invention is not limited to this embodiment. For example, in another embodiment, the heat dissipating abutting structure can be a protruding lug structure.

Understandably, the number and the configuration of the heat dissipating abutting structure are not limited to those illustrated in the figures of this embodiment. It depends on practical demands.

Besides, as shown in FIG. 1 to FIG. 4, the first end and the second end of the first heat dissipating portion 1311 are integrally connected to the second heat dissipating portion 1312 and the third heat dissipating portion 1313 respectively, which results in a low heat resistance between the first heat dissipating portion 1311 and the second heat dissipating portion 1312 and a low heat resistance between the first heat dissipating portion 1311 and the third heat dissipating portion 1313. Therefore, the heat conducted to the first heat dissipating portion 1311 can be rapidly conducted to the second heat dissipating portion 1312 and the third heat dissipating portion 1313. Furthermore, in order to allow the second heat dissipating portion 1312 and the third heat dissipating portion 1313 to dissipate the heat to the air rapidly, a second heat dissipating structure 13121 and a third heat dissipating structure 13131 are respectively formed on the second heat dissipating portion 1312 and the third heat dissipating portion 1313 and for increasing a heat dissipating area of the second heat dissipating portion 1312 and a heat dissipating area of the third heat dissipating portion 1313.

In this embodiment, similar to the first heat dissipating structure 13112 and the heat dissipating structure 1322, the second heat dissipating structure 13121 and the third heat dissipating structure 13131 can be two thermal fin structures, such as two plate-fin structures. However, the present invention is not limited to this embodiment. For example, in another embodiment, the second heat dissipating structure or the third heat dissipating structure can be a column-fin structure.

Specifically, as shown in FIG. 3 to FIG. 5, the first case portion 111 includes a first wall 111A, a second wall 111B, a third wall 111C and a fourth wall 111D. The first wall 111A and the second wall 111B are located opposite to each other. The third wall 111C and the fourth wall 111D are located opposite to each other and connected to the first wall 111A and the second wall 111B. The first wall 111A is located adjacent to the first heat dissipating portion 1311. The first slot structure 1111 is formed on the first wall 111A. The third wall 111C is located adjacent to the second heat dissipating portion 1312. The fourth wall 111D is located adjacent to the third heat dissipating portion 1313. The second case portion 112 includes a fifth wall 112A, a sixth wall 112B, a seventh wall 112C and an eighth wall 112D. The fifth wall 112A and the sixth wall 112B are located opposite to each other. The seventh wall 112C and the eighth wall 112D are located opposite each other and connected to the fifth wall 112A and the sixth wall 112B. The fifth wall 112A is located adjacent to the second heat dissipating component 132. The second slot structure 1121 is formed on the fifth wall 112A. The seventh wall 112C is located adjacent to the second heat dissipating portion 1312. The eighth wall 112D is located adjacent to the third heat dissipating portion 1313. The heat dissipating abutting structure 1122 is formed on the sixth wall 112B.

In addition, as shown in FIG. 3 to FIG. 5, a thickness of the first heat dissipating portion 1311 along the first direction D1 is greater than a thickness of the second heat dissipating portion 1312 along a second direction D2 and greater than a thickness of the third heat dissipating portion 1313 along the second direction D2. A length of the first heat dissipating portion 1311 along the second direction D2 is greater than a length of the case device 11 along the second direction D2. The thicker first heat dissipating portion 1311 can absorb more heat and conduct the heat to the thinner second heat dissipating portion 1312 and the thinner third heat dissipating portion 1313 located outside the case device 11 rapidly. Therefore, the first heat dissipating component 131 has enhanced heat dissipating performance. Preferably, the first direction D1 can be perpendicular to the second direction D2, and the first direction D1 and the second direction D2 can be perpendicular to the inserting direction I of the first electrical plug connector 21 and/or the second electrical plug connector 22.

Understandably, the sizes of the first heat dissipating portion, the second heat dissipating portion and the third heat dissipating portion are not limited to this embodiment. It depends on practical demands.

As shown in FIG. 3 to FIG. 6, at least one first engaging structure 1112 is formed on the first case portion 111. At least one second engaging structure 1123 is formed on the second case portion 112. The second case portion 112 is detachably assembled with the first case portion 111 by an engagement of the at least one second engaging structure 1123 and the at least one first engaging structure 1112. When the second case portion 112 is detachably assembled with the first case portion 111, the first case portion 111 and the second case portion 112 can cooperatively form the first receiving space S, which is shown in FIG. 6, for at least partially accommodating the first heat dissipating portion 1311.

In this embodiment, the first engaging structure 1112 can be a protruding structure. The second engaging structure 1123 can be a notch structure. However, the present invention is not limited to this embodiment. For example, in another embodiment, the first engaging structure and the second engaging structure can be an engaging protrusion and an engaging recess.

Understandably, the numbers and the configurations of the first engaging structure and the second engaging structure are not limited to those illustrated in the figures of this embodiment. It depends on practical demands.

Specifically, the third wall 111C and the fourth wall 111D do not protrude out of the first wall 111A. The seventh wall 112C and the eighth wall 112D protrude out of the sixth wall 112B. The first receiving space S is defined by the first wall 111A, the sixth wall 112B, the seventh wall 112C and the eighth wall 112D. The seventh wall 112C does not contact with the third wall 111C, so that the first lateral window O1 is defined between the seventh wall 112C and the third wall 111C and for allowing the first end of the first heat dissipating portion 1311 to pass therethrough. The eighth wall 112D does not contact with the fourth wall 111D, so that the first lateral window O2 is defined between the eighth wall 112D and the fourth wall 111D and for allowing the second end of the first heat dissipating portion 1311 to pass therethrough.

As shown in FIG. 3 to FIG. 6, the first engaging structure 1112 and the second engaging structure 1123 are respectively located at a rear side of the first case portion 111 and a rear side of the second case portion 112. Therefore, in order to increase an overall structural strength, a first supporting structure 1113 is formed on the first case portion 111. A second supporting structure 1124 is formed on the second case portion 112. When the second case portion 112 is detachably assembled with the first case portion 111, the first supporting structure 1113 and the second supporting structure 1124 abut against the second case portion 112 and the first case portion respectively. The first supporting structure 1113 and the second supporting structure 1124 are respectively located at a front side of the first case portion 111 and a front side of the second case portion 112 for positioning the front side of the first case portion 111 and the front side of the second case portion 112. However, the present invention is not limited to this embodiment. For example, in another embodiment, the first supporting structure 1113 and/or the second supporting structure 1124 can be omitted.

Furthermore, in order to make sure that the front side of the second case portion 112 and the front side of the first case portion 111 are not displaced, at least one first positioning structure 1114 is formed on the first case portion. At least one first positioning portion 11241 is formed on the second supporting structure 1124. At least one second positioning structure 1125 is formed on the second case portion 112. At least one second positioning portion 11131 is formed on the first supporting structure 1113. When the first supporting structure 1113 and the second supporting structure 1124 respectively abut against the second case portion 112 and the first case portion 111, each first positioning structure 1114 and each second positioning structure 1125 respectively pass through and engage with the corresponding first positioning portion 11241 and the corresponding second positioning portion 11131 for positioning the first case portion 111 and the second case portion 112.

Furthermore, a plurality of snapping portions 141 are formed on the covering body 14. At least one first snapping structure 1115 and at least one second snapping structure 1126 are respectively formed on the first case portion 111 and the second case portion 112. The first snapping structure 1115 and the second snapping structure 1126 are used to be engaged with the corresponding snapping portions 141 for achieving assembly of the covering body 14 and the case device 11.

In this embodiment, when it is desired to assemble the electrical receptacle connector 1, a user can stack the first case portion 111, the first heat dissipating portion 1311 and the second case portion 112 along the first direction D1 sequentially and respectively engage the first engaging structure 1112, the first positioning structure 1114 and the second positioning structure 1125 with the second engaging structure 1123, the first positioning portion 11241 and the second positioning portion 11131, so as to achieve assembly of the first heat dissipating component 131 and the case device 11. Afterwards, the user can assemble the covering body 14 with the case device 11 by an engagement of the first snapping structure 1115 and the snapping portion 141 and an engagement of the second snapping structure 1126 and the snapping portion 141, and then assemble the finger device 15 with the case device 11. After the covering body 14 and the finger device 15 are assembled with the case device 11, the user can place the second heat dissipating component 132 on the fifth wall 112A of the second case portion 112 and then engage the clipping component 16 with the case device 11 to clamp the second heat dissipating component 132 by the engagement of the clipping component 16 and the case device 11. From the above, the electrical receptacle connector 1 has an advantage of easy assembly.

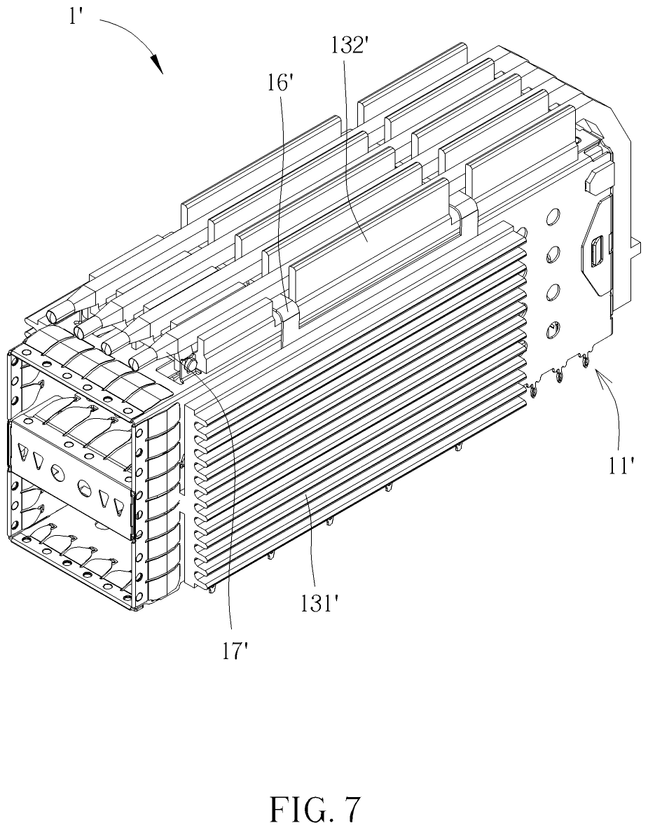

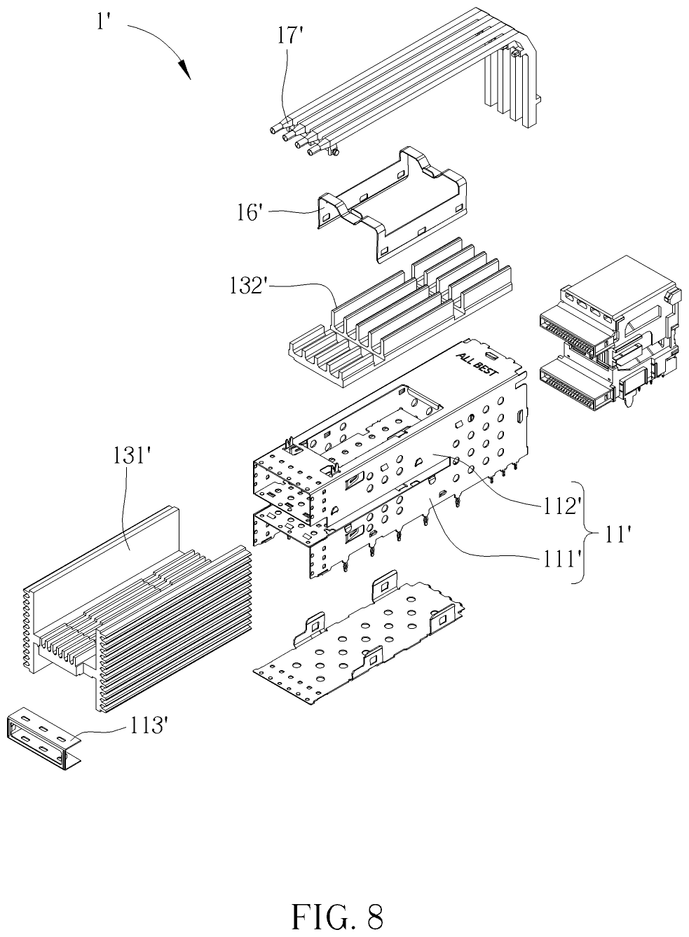

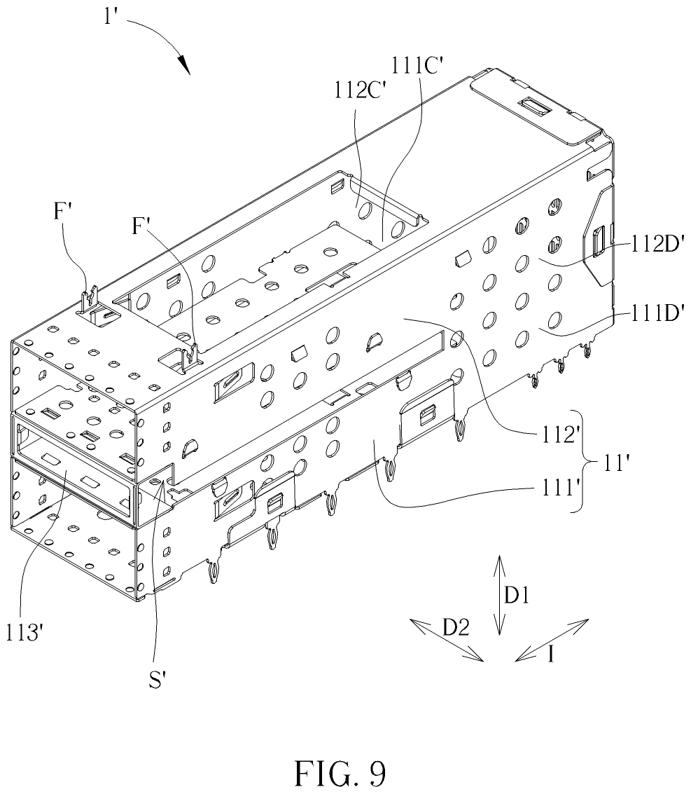

Please refer to FIG. 7 to FIG. 9. FIG. 7 is a schematic diagram of an electrical receptacle connector 1′ according to a second embodiment of the present invention. FIG. 8 is a partial exploded diagram of the electrical receptacle connector 1′ according to the second embodiment of the present invention. FIG. 9 is a partial diagram of the electrical receptacle connector 1′ according to the second embodiment of the present invention. As shown in FIG. 7 to FIG. 9, different from the first embodiment, a seventh wall 112C′ and a eighth wall 112D′ of a second case portion 112′ are respectively integrally connected to a third wall 111C′ and a fourth wall 111D′ of a first case portion 111′. A case device 11′ further includes a supporting component 113′. The supporting component 113′ abuts against the first case portion 111′ and the second case portion 112′ and is at least partially accommodated in a first receiving space S′, i.e., in this embodiment, there is no first positioning structure and no first supporting structure formed on the first case portion 111′, and there is no second positioning structure and no second supporting structure formed on the second case portion 112′. The user can at least partially insert a first heat dissipating portion 1311′ of a first heat dissipating component 131′ into the first receiving space S′ through an opening of the first receiving space S′ along the inserting direction I and engage the first heat dissipating portion 1311′ of the first heat dissipating component 131′ with the first case portion 111′ and the second case portion 112′, so as to achieve assembly of the first heat dissipating component 131′ and the case device 11′.

Understandably, in another embodiment, there can be only one of the seventh wall and the eighth wall of the second case portion integrally connected to a corresponding one of the third wall and the fourth wall of the first case portion.

It should be noticed that in this embodiment, the opening of the first receiving space S′ and an opening of the first lateral windows are facing forward, i.e., the first heat dissipating portion 1311′ of the first heat dissipating component 131′ and the supporting component 113′ are at least partially inserted into the first receiving space S′ from front to rear. However, the present invention is not limited to this embodiment. For example, in another embodiment, the opening of the first receiving space and the opening of the first lateral window can be facing rearward, i.e., the first heat dissipating portion of the first heat dissipating component and the supporting component can be at least partially inserted into the first receiving space from rear to front.

Besides, the electrical receptacle connector 1′ further includes at least one light guiding component 17′. The light guiding component 17′ is fixed on the second case portion 112′ by at least one fixing structure F′ and located above a clipping component 16′. After the second heat dissipating component 132′ is clamped by and located between the second case portion 112′ and the clipping component 16′, the light guiding component 17′ can be fixed on the second case portion 112′ and arranged to be at least partially located between two corresponding fins of a heat dissipating structure 1322′ of the second heat dissipating component 132′ and to extend along the heat dissipating structure 1322′.

Other details of this embodiment are similar to the ones of the first embodiment. Detailed description is omitted herein for simplicity.

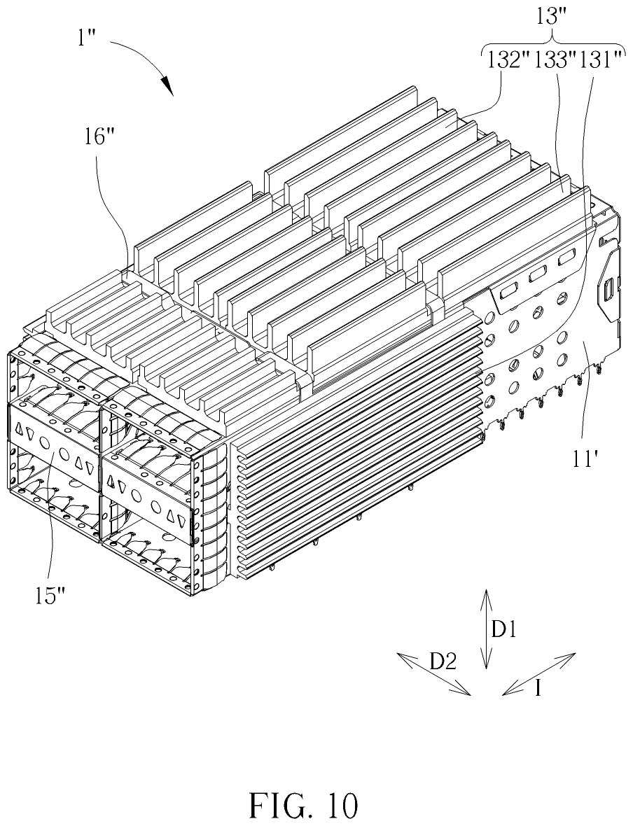

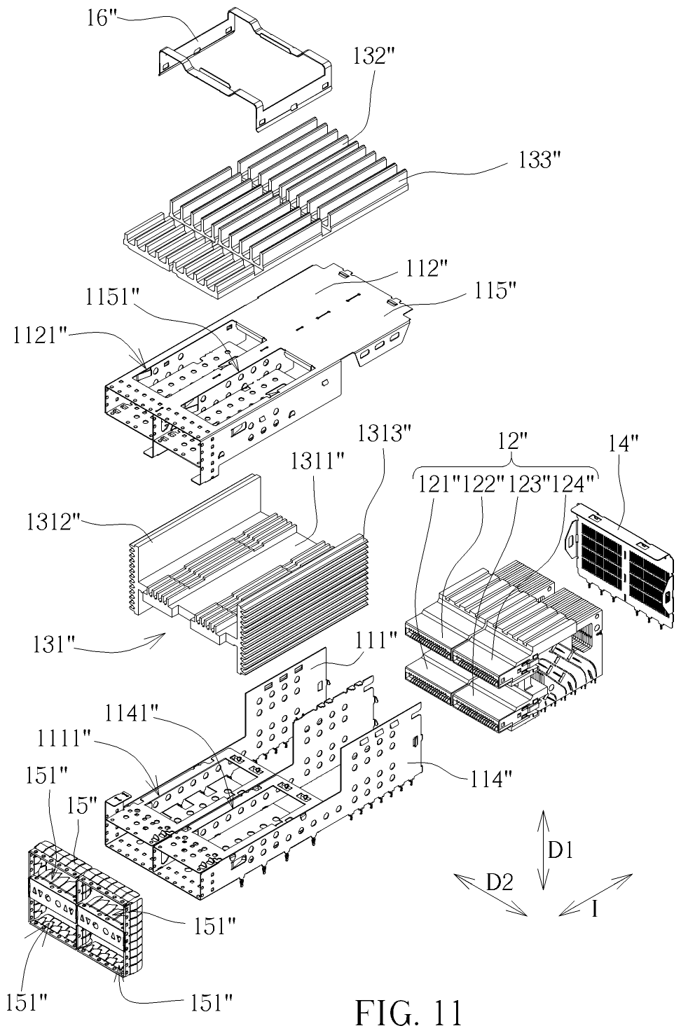

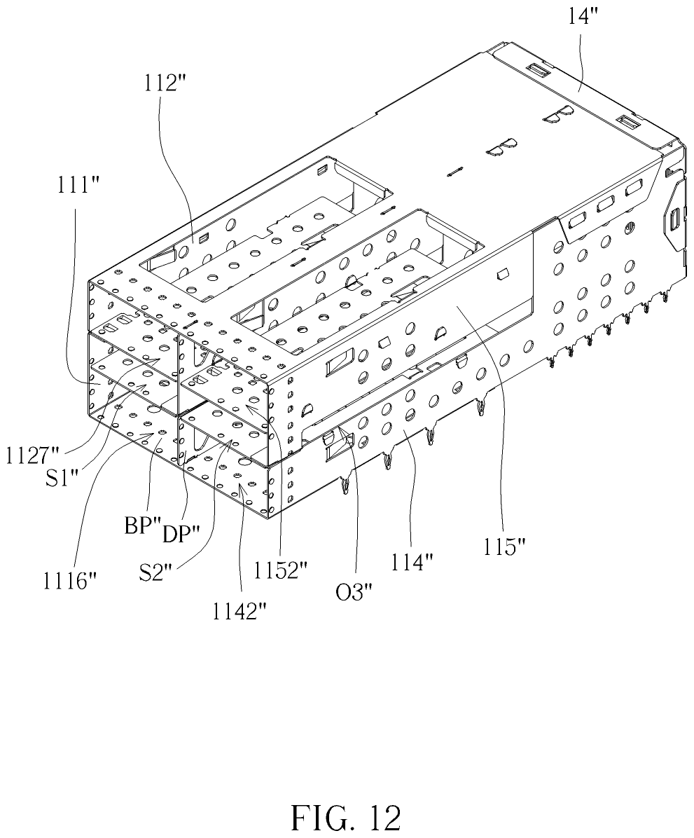

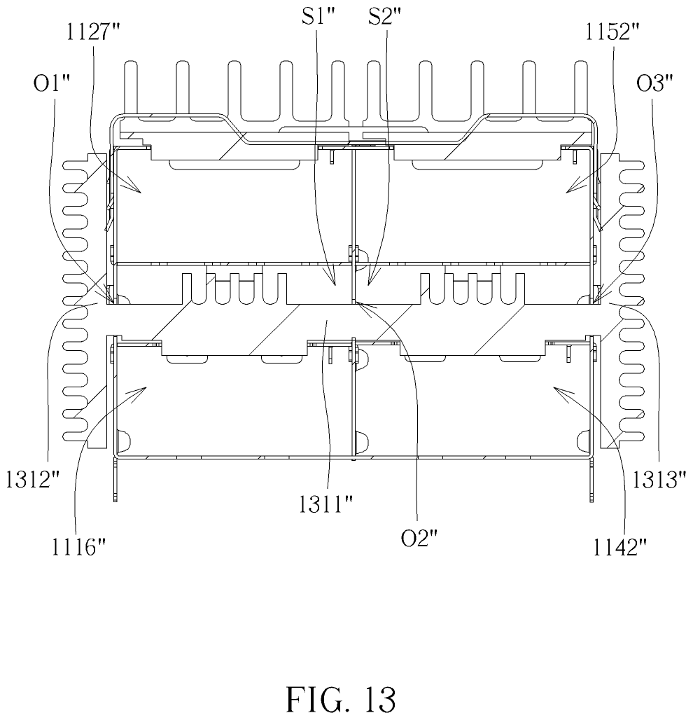

Please refer to FIG. 10 to FIG. 13. FIG. 10 is a schematic diagram of an electrical receptacle connector 1″ according to a third embodiment of the present invention. FIG. 11 is a partial exploded diagram of the electrical receptacle connector 1″ according to the third embodiment of the present invention. FIG. 12 is a partial diagram of the electrical receptacle connector 1″ according to the third embodiment of the present invention. FIG. 13 is a sectional diagram of the electrical receptacle connector 1″ according to the third embodiment of the present invention. As shown in FIG. 10 to FIG. 13, different from the first embodiment, a case device 11″ includes a first case portion 111″, a second case portion 112″, a third case portion 114″ and a fourth case portion 115″. A terminal device 12″ includes a first contact set 121″, a second contact set 122″, a third contact set 123″ and a fourth contact set 124″. A heat dissipating device 13″ further includes a first heat dissipating component 131″, a second heat dissipating component 132″ and a third heat dissipating component 133″. A first slot structure 1111″, a second slot structure 1121″, a third slot structure 1141″ and a fourth slot structure 1151″ are respectively formed on the first case portion 111″, the second case portion 112″, the third case portion 114″ and the fourth case portion 115″. A first accommodating space 1116″, a second accommodating space 1127″, a third accommodating space 1142″ and a fourth accommodating space 1152″ are respectively formed on the first case portion 111″, the second case portion 112″, the third case portion 114″ and the fourth case portion 115″. The first case portion 111″ and the second case portion 112″ are arranged along the first direction D1. The third case portion 114″ and the fourth case portion 115″ are arranged along the first direction D1. The third case portion 114″ and the first case portion 111″ are arranged along the second direction D2. The fourth case portion 115″ and the second case portion 112″ are arranged along the second direction D2. The first case portion 111″ and the second case portion 112″ cooperatively define a first receiving space S1″ between the first accommodating space 1116″ and the second accommodating space 1127″ and two first lateral windows O1″, O2″ located at two opposite sides of the first receiving space S1″. The third case portion 114″ and the fourth case portion 115″ cooperatively define a second receiving space S2″ between the third accommodating space 1142″ and the fourth accommodating space 1152″ and a second lateral window O3″ located at a side of the second receiving space S2″. The first contact set 121″, the second contact set 122″, the third contact set 123″ and the fourth contact set 124″ are respectively at least partially located inside the first accommodating space 1116″, the second accommodating space 1127″, the third accommodating space 1142″ and the fourth accommodating space 1152″. A first heat dissipating portion 1311″ of the first heat dissipating component 131″ is at least partially disposed inside the first receiving space S1″ and the second receiving space S2″ and passes through the first lateral windows O1″, O2″ and the second lateral window O3″. A second heat dissipating portion 1312″ and a third heat dissipating portion 1313″ of the first heat dissipating component 131″ are respectively integrally connected to the first end and the second end of the first heat dissipating portion 1311″ respectively protruding out of the first lateral window O1″ and the second lateral window O3″. A first abutting structure and a first auxiliary abutting structure are formed on the first heat dissipating portion 1311″ and respectively pass through the first slot structure 1111″ and the third slot structure 1141″. The second case portion 112″ and the fourth case portion 115″ respectively abut against two first heat dissipating structures formed on the first heat dissipating portion 1311″. The first case portion 111″, the second case portion 112″, the third case portion 114″ and the fourth case portion 115″ are respectively at least partially located between the second heat dissipating portion 1312″ and the third heat dissipating portion 1313″. The second heat dissipating component 132″ is disposed on a side of the second case portion 112″ away from the first heat dissipating portion 1311″ and at least partially passes through the second slot structure 1121″. The third heat dissipating component 133″ is disposed on a side of the fourth case portion 115″ away from the first heat dissipating portion 1311″ and at least partially passes through the fourth slot structure 1151″.

Furthermore, a covering body 14″ is assembled with the case device 11′ by engaging the covering body 14″ with the first case portion 111″, the second case portion 112″, the third case portion 114″ and the fourth case portion 115″. Four opening portions 151″ are formed on a finger device 15″ and respectively located at positions corresponding to the first case portion 111″, the second case portion 112″, the third case portion 114″ and the fourth case portion 115″. The finger device 15″ is assembled with the case device 11′ along the inserting direction I and for preventing an electromagnetic interference. A clipping component 16″ is engaged with the second case portion 112″ and the fourth case portion 115″, so that the second heat dissipating component 132″ is clamped by and located between the clipping component 16″ and the second case portion 112″, and the third heat dissipating component 133″ is clamped by and located between the clipping component 16″ and the fourth case portion 115″.

In order to make an overall structure reasonable and compact, the first case portion 111″ and the third case portion 114″ can be integrated into a first case assembly, i.e., parts of the first case portion 111″ and the third case portion 114″ can be defined by different portions of a same element. For example, a second wall of the first case portion 111″ and a wall of the third case portion 114″ corresponding to the second wall of the first case portion 111″ can be respectively defined by a left half portion and a right half portion of a bottom plate BP″, and a fourth wall of the first case portion 111″ and a wall of the third case portion 114″ corresponding to the fourth wall of the first case portion 111″ can be respectively defined by a left half portion and a right half portion of a detachable dividing plate DP″. Similarly, the second case portion 112″ and the fourth case portion 115″ can be integrated into a second case assembly. Besides, the numbers and the configurations of the engaging structure and the positioning structure of each case portion are different from the ones of the first embodiment. It should be noticed that an assembling process of the first heat dissipating component 131″ and the case device 11″ of this embodiment is similar to an assembling process of the first heat dissipating component 131 and the case device 11 of the first embodiment. In other words, in this embodiment, the user can stack the first heat dissipating portion 1311″ above the first case portion 111″ and the third case portion 114″, i.e., the first case assembly, along the first direction D1 and then stack the second case portion 112″ and the fourth case portion 115″, i.e., the second case assembly, above the first heat dissipating portion 1311″ along the first direction D1, so as to achieve assembly of the first heat dissipating component 131″ and the case device 11″.

Other details of this embodiment are similar to the ones of the first embodiment. Detailed description is omitted herein for simplicity.

In summary, in the present invention, the first heat dissipating component is the one-piece structure, and due to a low heat resistance between the first heat dissipating portion and the second heat dissipating portion and a low heat resistance between the first heat dissipating portion and the third heat dissipating portion are low, heat conducted to the first heat dissipating portion can be conducted to the second heat dissipating portion and the third heat dissipating portion rapidly. Besides, when it is desired to assemble the electrical receptacle connector, it only has to stack the first case portion, the first heat dissipating portion and the second case portion along the first direction sequentially, or insert the first heat dissipating portion into the first receiving space between the first case portion and the second case portion along the inserting direction, for achieving assembly of the first heat dissipating component and the case device. Therefore, the electrical receptacle connector has an advantage of easy assembly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrical receptacle connector comprising:
a case device comprising:
a first case portion, a first slot structure and a first accommodating space being formed on the first case portion; and
a second case portion, a second slot structure and a second accommodating space being formed on the second case portion, the first case portion and the second case portion being arranged along a first direction, the first case portion and the second case portion cooperatively defining a first receiving space located between the first accommodating space and the second accommodating space and two first lateral windows located at two opposite sides of the first receiving space;
a terminal device comprising:
a first contact set at least partially disposed inside the first accommodating space; and
a second contact set at least partially disposed inside the second accommodating space; and
a heat dissipating device comprising:
a first heat dissipating component being a one-piece structure and comprising:
a first heat dissipating portion at least partially disposed inside the first receiving space and passing through the two first lateral windows, a first abutting structure being formed on the first heat dissipating portion;
a second heat dissipating portion integrally connected to a first end of the first heat dissipating portion; and
a third heat dissipating portion integrally connected to a second end of the first heat dissipating portion opposite to the first end of the first heat dissipating portion, the first case portion and the second case portion being at least partially located between the second heat dissipating portion and the third heat dissipating portion.

2. The electrical receptacle connector of claim 1, wherein a thickness of the first heat dissipating portion along the first direction is greater than a thickness of the second heat dissipating portion along a second direction and greater than a thickness of the third heat dissipating portion along the second direction, and the first direction is perpendicular to the second direction.

3. The electrical receptacle connector of claim 1, wherein a length of the first heat dissipating portion along a second direction is greater than a thickness of the case device along the second direction, and the first direction is perpendicular to the second direction.

4. The electrical receptacle connector of claim 1, wherein at least one wall of the second case portion is integrally connected to at least one wall of the first case portion, the case device further comprises a supporting component abutting against the first case portion and the second case portion and at least partially located inside the first receiving space, and the first heat dissipating component is assembled with the case device by at least inserting the first heat dissipating portion into the first receiving space along an inserting direction different from the first direction.

5. The electrical receptacle connector of claim 1, wherein at least one first engaging structure is formed on the first case portion, at least one second engaging structure is formed on the second case portion, the second case portion is detachably assembled with the first case portion by an engagement of the at least one second engaging structure and the at least one first engaging structure, at least one supporting structure is formed on one of the first case portion and the second case portion, the at least one supporting structure abuts against another one of the first case portion and the second case portion when the second case portion is detachably assembled with the first case portion, and the first heat dissipating component is assembled with the case device by stacking the first case portion, the first heat dissipating portion and the second case portion along the first direction sequentially.

6. The electrical receptacle connector of claim 1, wherein a first heat dissipating structure is formed on the first heat dissipating portion and for increasing a heat dissipating area of the first heat dissipating portion, and a heat dissipating abutting structure is formed on the second case portion and abuts against the first heat dissipating structure.

7. The electrical receptacle connector of claim 1, further comprising a clipping component and a second heat dissipating component disposed on a side of the second case portion away from the first heat dissipating portion, an abutting structure and a heat dissipating structure being formed on the second heat dissipating component, the abutting structure at least partially passing through the second slot structure, the heat dissipating structure being for increasing a heat dissipating area of the second heat dissipating component, and the second heat dissipating component being clamped by and located between the clipping component and the case device.

8. The electrical receptacle connector of claim 7, further comprising at least one light guiding component fixed on the second case portion, the heat dissipating structure being a plate-fin structure, and the at least one light guiding component being partially located between two corresponding fins of the plate-fin structure.

9. The electrical receptacle connector of claim 1, further comprising a finger device assembled with the case device and for preventing an electromagnetic interference.

10. The electrical receptacle connector of claim 1, wherein a height of the first accommodating space along the first direction is equal to a height of the second accommodating space along the first direction and greater than a height of the first receiving space along the first direction.

11. The electrical receptacle connector of claim 1, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

12. The electrical receptacle connector of claim 2, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along the second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion.

13. The electrical receptacle connector of claim 3, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along the second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion.

14. The electrical receptacle connector of claim 4, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

15. The electrical receptacle connector of claim 5, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

16. The electrical receptacle connector of claim 6, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

17. The electrical receptacle connector of claim 7, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

18. The electrical receptacle connector of claim 8, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

19. The electrical receptacle connector of claim 9, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.

20. The electrical receptacle connector of claim 10, wherein the case device further comprises a third case portion and a fourth case portion, a third slot structure and a third accommodating space are formed on the third case portion, a fourth slot structure and a fourth accommodating space are formed on the fourth case portion, the third case portion and the fourth case portion are arranged along the first direction, the third case portion and the fourth case portion cooperatively define a second receiving space located between the third accommodating space and the fourth accommodating space and a second lateral window located at a side of the second receiving space, the third case portion and the first case portion are arranged along a second direction, the fourth case portion and the second case portion are arranged along the second direction, the terminal device further comprises a third contact set and a fourth contact set, the third contact set is at least partially disposed inside the third accommodating space, the fourth contact set is at least partially disposed inside the fourth accommodating space, the first heat dissipating portion is disposed inside the first receiving space and the second receiving space and passes through the two first lateral windows and the second lateral window, the first abutting structure and a first auxiliary abutting structure are formed on the first heat dissipating portion and respectively pass through the first slot structure and the third slot structure, the second case portion and the fourth case portion abut against the first heat dissipating portion, the first case portion, the second case portion, the third case portion and the fourth case portion are at least partially located between the second heat dissipating portion and the third heat dissipating portion, and the first direction is perpendicular to the second direction.
